(19) United States
(12) Patent Application Publication
(10) Pub. No.: US 2021/0388666 A1
(43) Pub. Date: Dec. 16, 2021

(54) INSULATING GLAZING WITH LUMINESCENT SOLAR CONCENTRATOR FOR PRODUCTION OF ELECTRICAL ENERGY

(71) Applicants: UNIVERSITA'DEGLI STUDI DI MILANO-BICOCCA, Milano (IT); GLASS TO POWER S.P.A., Rovereto (TN) (IT)

(72) Inventors: Francesco MEINARDI, Lecco (IT); Sergio BROVELLI, Milano (IT); Francesco BRUNI, Cernusco su! Navigiio (MI) (IT); Marina GANDINI, Milano (IT)

(73) Assignees: UNIVERSITA' DEGLI STUDI DI MILANO - BICOCCA, Milano (IT); GLASS TO POWER S.P.A., Rovereto (TN) (IT)

(21) Appl. No.: 17/289,507

(22) PCT Filed: Oct. 28, 2019
(86) PCT No.: PCT/IB2019/059229

§ 371 Date: Apr. 28, 2021

(30) Foreign Application Priority Data
Oct. 30, 2018 (IT) 102018000009908

(51) Int. Cl. E06B 3/663; H01L 31/054; E06B 9/24

(52) U.S. Cl. CPC E06B 3/66347; H01L 31/0547; E06B 2003/66395; E06B 2009/2476; E06B 9/24

(57) ABSTRACT

An insulating glazing having at least two panels made of transparent or semi-transparent material is provided. At least one of these panels is a luminescent solar concentrator.

The subject of the present invention is insulating glazing according to the preamble of the main claim.

As is known, multi-glass insulating glazing is constituted by at least two vitreous or plastics panels which are transparent or semi-transparent, and are separated from one another by sealed spacers. Between the panels there is thus present a chamber usually filled with gas which has low thermal conductivity (for example argon, krypton), making it possible to improve the thermal insulation of the insulating glazing.

In this conventional architecture, the insulating glazing is used to constitute continuous glass walls in buildings with a continuous facade, and to close openings of windows, French windows or the like (and in this case they are provided with a frame). However, the known insulating glazing does not make it possible to produce energy from the solar radiation which strikes its panels.

Luminescent solar concentrators are also known which are particularly suitable for transforming the solar radiation supplied to them into electrical energy.

As is known, luminescent solar concentrators (or LSCs) comprise a glass or plastics waveguide which defines the body of the concentrator, which body is coated or doped with highly emissive elements or components commonly known as fluorophores. The direct and/or diffused sunlight is absorbed by these fluorophores, and is re-emitted with a greater wavelength. The luminescence thus generated is propagated by means of total internal reflection to the edges of the waveguide, and is converted into electrical energy by photovoltaic cells which are coupled to the perimeter of the body of the concentrator.

By selecting appropriately the concentration of fluorophores in the waveguide and their optical properties, it is possible to produce coloured or colourless devices with the required level of transparency and an arbitrary form, which devices can easily be integrated architecturally as photovoltaic insulating glazing for example.

US2014/130864 describes a transparent solar concentrator used in a window of the type with two panels, each of which can comprise a solar concentrator.

WO2015/152011 describes a multi-layer panel comprising two glass panels between which there is placed a flat element made of resin. Spacers are placed between the panels and the element made of resin, whereas the element made of resin is inserted, at a perimeter portion thereof, within a groove in a metal frame disposed between said spacers. Sealing elements are placed between the glass panels and the metal frame within a hollow space which is present between the panels and the element made of resin.

In the groove in the metal frame there is placed a pad material which can receive the adjacent edge of the element made of resin; this pad material need also not be placed on both the sides of the frame, or it can be disposed partially within the groove.

The use of the flat element made of resin is necessary since it can improve the resistance to breakage of the multi-layer panel.

WO2018/132491 describes a window which can generate electricity, and comprises a first and a second flat element made of glass, and a device which can generate electricity if it is struck by sunlight, such as a photovoltaic device, provided on an inner surface of one of these flat elements.

The objective of the present invention is to provide insulating glazing, which as well as the advantages of thermal insulation, also has the possibility of transforming the solar radiation to which it is subjected into electrical energy.

Another objective is to provide insulating glazing wherein the solar cells which are coupled to the perimeter of the body of the solar concentrator constitute an electrical circuit which can generate a uniform quantity of electrical energy along the edges of the concentrator, independently of the fact that some sections of these edges, close to the corners, are reached by less radiation of light.

Another objective is to provide insulating glazing of the aforementioned type which has a long-lasting seal, i.e. photovoltaic insulating glazing wherein the gas with low thermal conductivity contained therein is not subject to leakages over a period of time. Another objective is to provide insulating glazing wherein the electrical energy generated can be transferred in a simple manner to batteries or to an electrical mains supply of the environment in which the insulating glazing is used.

A further objective is to provide insulating glazing which can be used as a source of supply of power to electrical and/or electronic devices which are used within an environment in which the insulating glazing is present, such as anti-theft devices, a Wi-Fi repeater, lighting elements or the like.

These objectives and others which will become apparent to persons skilled in the art are achieved by insulating glazing according to the main claim.

For better understanding of the present invention, purely by way of non-limiting indication, the following drawings are appended, in which:

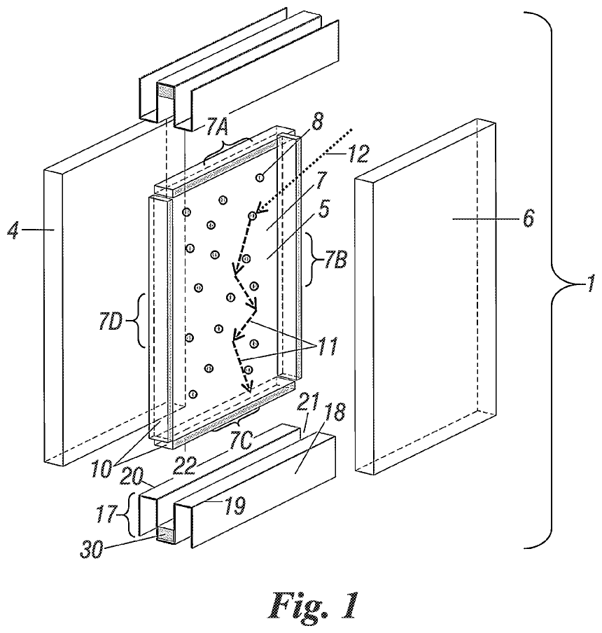

FIG. 1 shows an exploded view in perspective, with some parts omitted for the sake of greater clarity, of insulating glazing according to the invention;

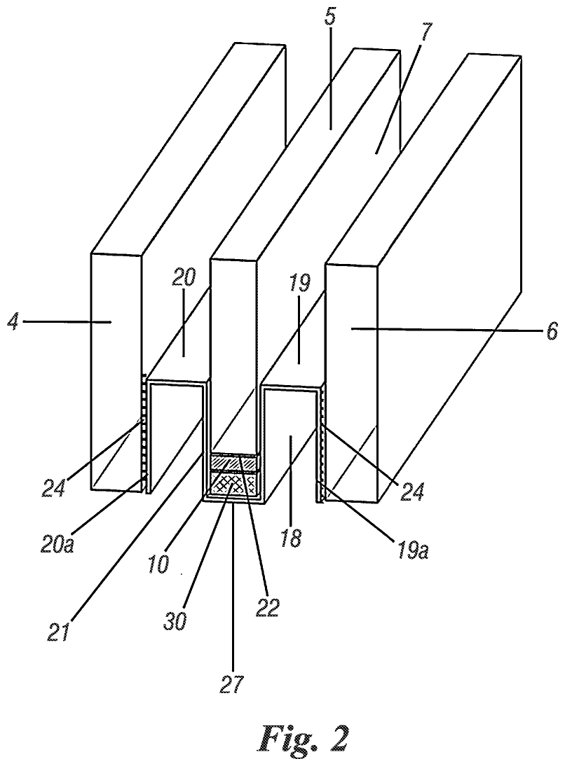

FIG. 2 shows an enlarged partial view in perspective of a lower portion of the insulating glazing in FIG. 1, with some parts omitted for the sake of greater clarity;

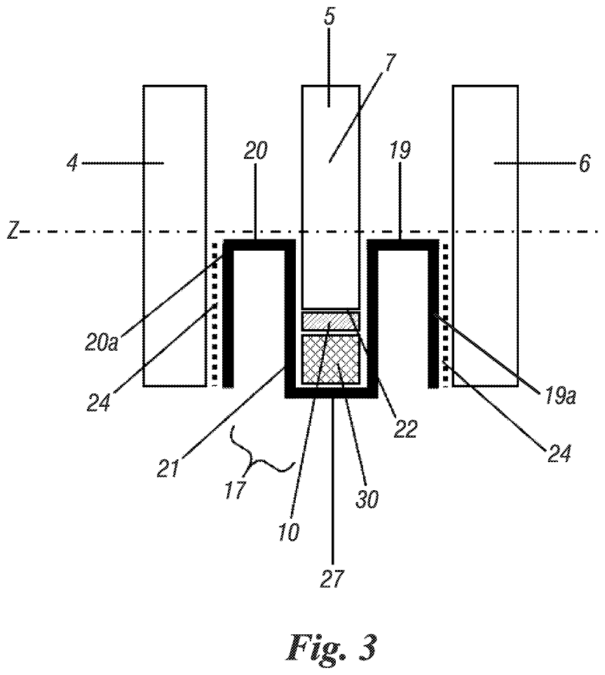

FIG. 3 shows a lateral view of what is shown in FIG. 2;

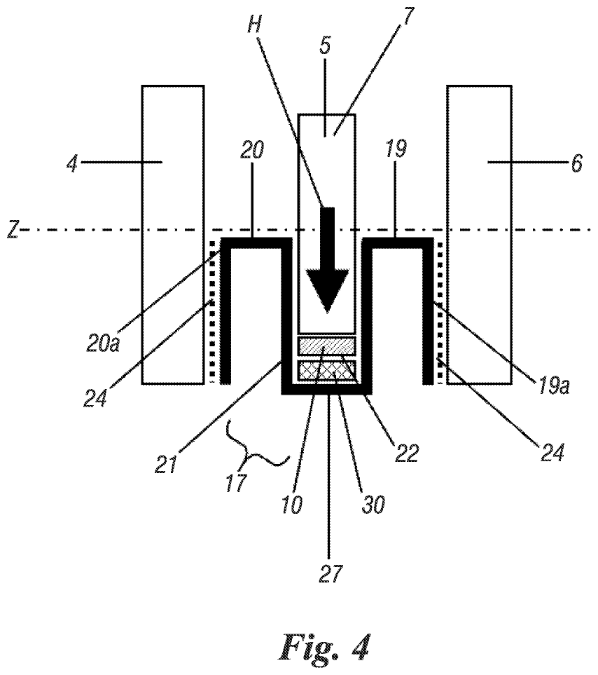

FIG. 4 shows a lateral view of what is shown in FIG. 3, but with a dimensional variation of a component of the insulating glazing in FIG. 1;

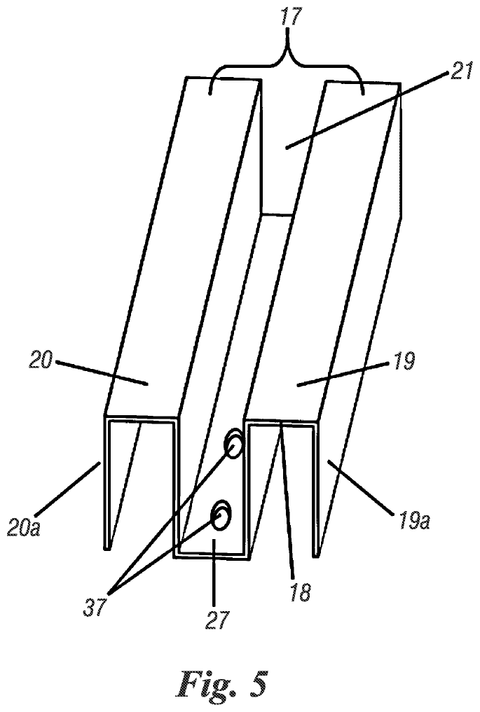

FIG. 5 shows a view in perspective of a component of the insulating glazing in FIG. 1;

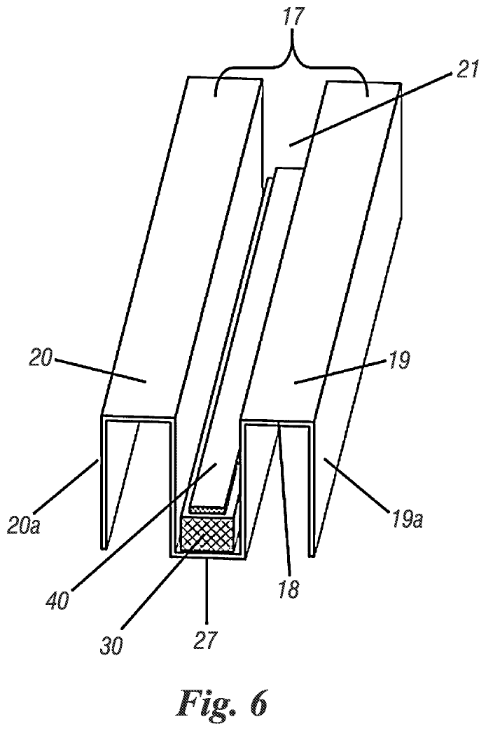

FIG. 6 shows a view in perspective of a variant of the component in FIG. 5;

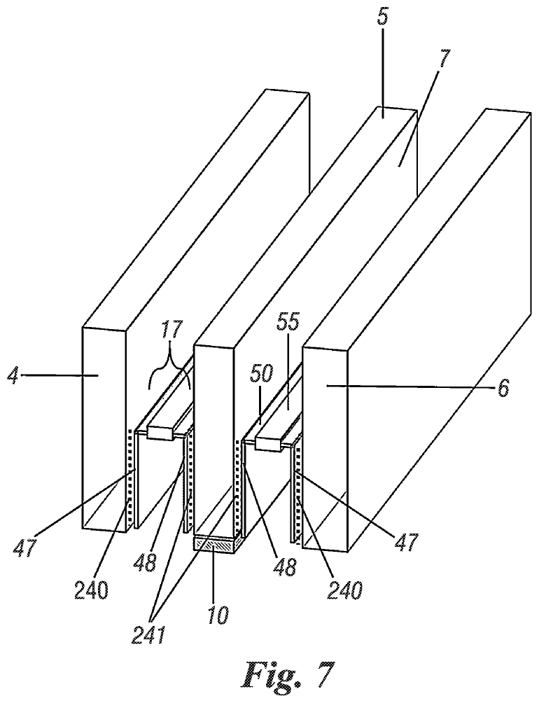

FIG. 7 shows a view similar to that in FIG. 2, but of a variant of the invention;

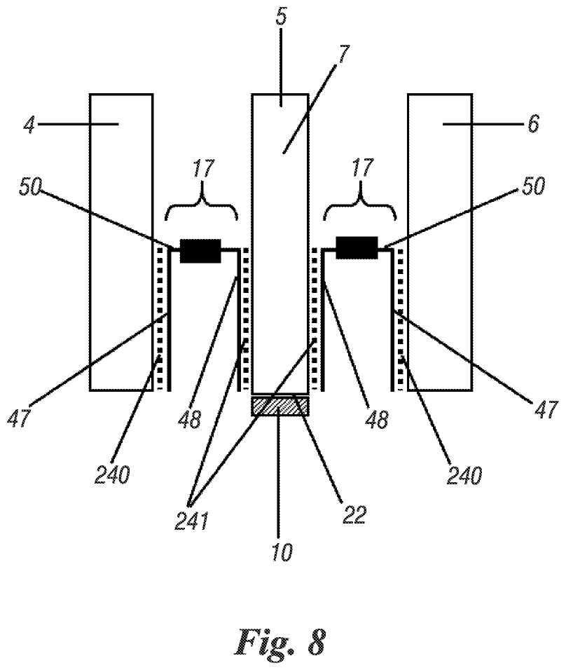

FIG. 8 shows a schematic lateral view of the variant in FIG. 7;

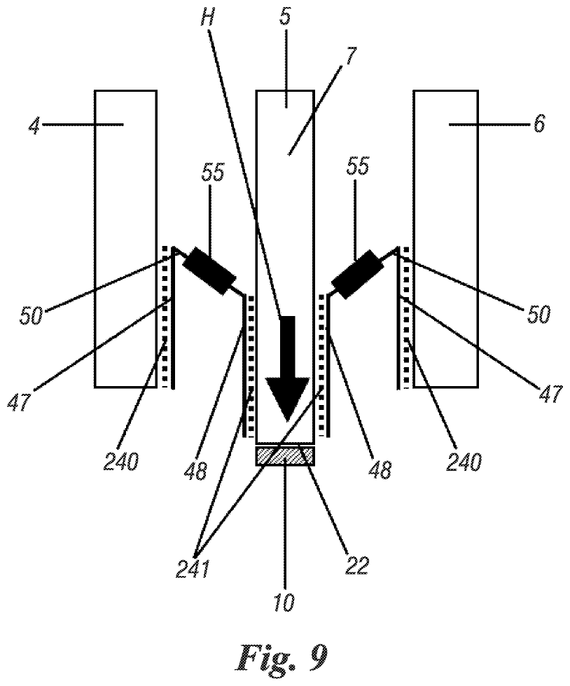

FIG. 9 shows a view similar to that in FIG. 8, but with a dimensional variation of a component of the insulating glazing in FIG. 7;

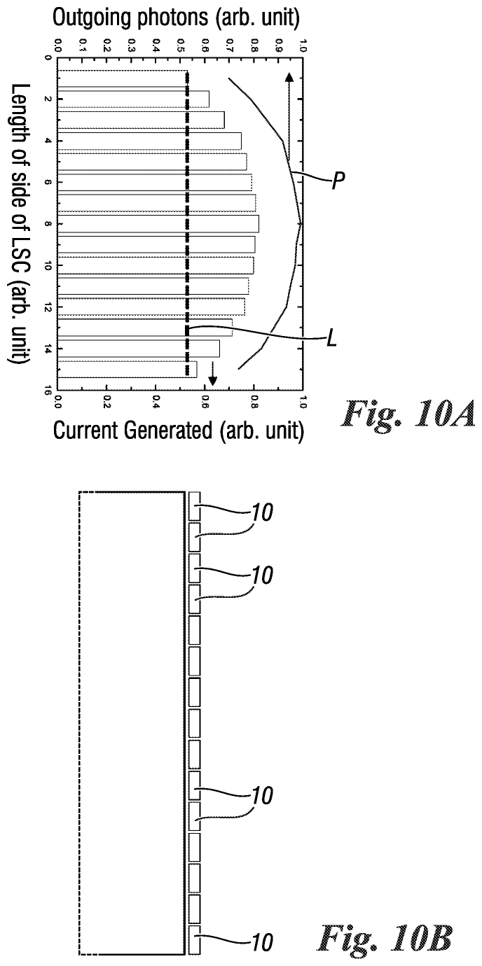

FIG. 10A shows a generic profile of emission of photons by the solar concentrator (continuous line P) and the histogram relating to the current produced by solar cells with a constant dimension coupled to the edge of the concentrator. In this configuration, the maximum current which can be obtained (broken line L) is limited by the current generated by the cells at the ends of the concentrator;

FIG. 10B shows schematically a lateral view of the solar concentrator with solar cells with identical dimensions;

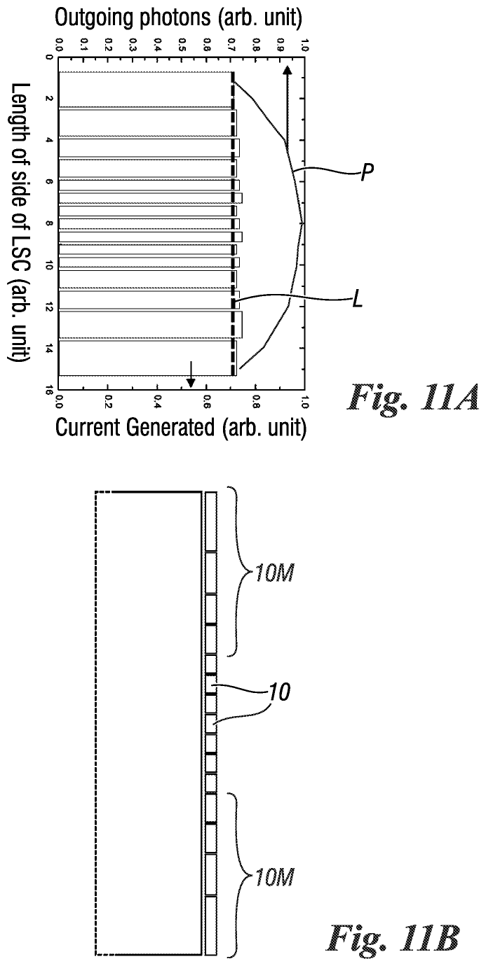

FIG. 11A shows the same profile of emission of photons by the solar concentrator (continuous line P) in FIG. 10 and the histogram relating to the current produced by solar cells with a variable dimension coupled to the edge of the concentrator itself, shown in FIG. 11B. In this configuration, the maximum current which can be obtained (broken line L) is independent from the emission profile along the edges; and

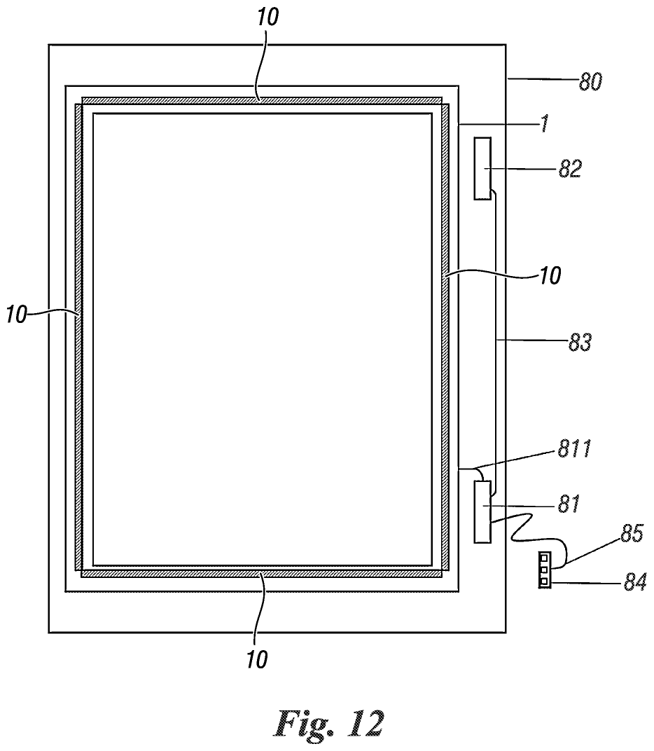

FIG. 12 shows schematically insulating glazing used in a self-powered “smart window”.

With reference to the aforementioned figures, insulating glazing is indicated as 1, and encloses a central portion defined by at least two panels; in the figures, by way of example, the insulating glazing comprises three panels: a first, outer panel 4, an intermediate panel 5, and an inner panel 6, where outer and inner refer to the environment in a single aperture or wall of which the insulating glazing is placed.

The outer panel 4 and the inner panel 6 are made of glass or of plastics material, whereas the intermediate panel 5 is a luminescent solar concentrator (LSC), of a type which in itself is known.

This concentrator or LSC 5 can be either in the form of a solid plate (such as the one in the figures), or a film disposed on a transparent support, for example a plastics material. As is known, the luminescent solar concentrator or LSC 5 also comprises a main body 7 made of glass or plastics material in which there are present emissive substances (which by way of example are shown in FIG. 1 as elements 8 which can clearly be identified within the body 7).

At edges 7A, 7B, 7C, 7D of the body 7 there are present known photovoltaic cells 10 which can collect the light radiation (indicated as 11 in FIG. 1) emitted by the emissive substances 8 which are present in the LSC, after the absorption by the substances of incident light radiation (indicated as 12 in FIG. 1) on the insulating glazing 1. These photovoltaic cells 10 are coupled optically in a known manner on the body 7 of the LSC 5.

By this means, use of the insulating glazing 1 as described above at a window, a French window (and in this case it is provided with a perimeter counter-frame 80, as shown in FIG. 12) or in order to define (together with other insulating glazing 1) the wall of an environment, makes it possible to obtain electrical energy from the light radiation which strikes the insulating glazing. However, the known plastics materials which constitute the luminescent solar concentrator 5, or, in any case, the set of materials present in the solar concentrator (produced either in the form of a solid plate or a film on a transparent support) have a coefficient of thermal expansion different from that of the glass of the panels 4 and 6. If this problem were not solved, using conventional architectures for standard insulating glazing, the insulating glazing would soon be damaged as a result of mechanical tensions associated with expansion and/or contraction of the structure.

According to the invention, this problem is solved by the use of spacer units (or simply “spacers”) 17 placed at the panels 4-6, which spacers can accept the expansion of the panels themselves, keeping unaltered the seal of the chamber which is present between the panels (and which chamber contains the gas with low thermal conductivity).

In addition, each spacer 17 has a receptacle to accommodate the electrical and photovoltaic components which are present on the perimeter of the luminescent solar concentrator, and permits the electrical contact between the components and the circuit for extraction of the electrical energy.

With reference in particular to FIGS. 1-6, each spacer 17 comprises a preformed body 18 with two portions 19 and 20 (formed substantially in the shape of an overturned “U”), which portions are placed at a short distance from one another and delimit a channel 21. A corresponding end 22 of the LSC 5 can be introduced into the channel. On the other hand the portions 19 and 20 have end walls 19A and 20A on the exterior of the spacer which are rendered integral with the panels 4 and 6 thanks to conventional adhesives and seals 24 (for example which are silicone-based).

The channel 21 accommodates the LSC composed of its body 7 and of the photovoltaic cells 10 which are coupled thereto. However, the luminescent solar concentrator or LSC 5 is not integral with the preformed spacer 17, since it is not connected by means of adhesives or adhesive layers to the body 18 of this spacer. The LSC is therefore free to slide in the channel, towards a wall 27 which at the bottom (with reference to the figures) delimits the channel 21 (and connects the portions 19 and 20). This provides the spacer 17 with the possibility of tolerating any expansions or contractions of the luminescent solar concentrator 5.

The spacer 17 can also permit the insertion into the channel 21 of a compensator element 30 which can compensate for the thermal expansion and/or contraction of the LSC 5, in a direction orthogonal to an axis which is perpendicular to the aforementioned wall 27. By way of non-limiting example, this element can be made of a plastic or rubbery material or a foam.

FIG. 4 represents schematically the operating principle of the above-described spacer 17 in the case in which the luminescent solar concentrator expands after a variation of temperature; this expansion (indicated by the arrow H) takes place perpendicularly to an axis Z which is orthogonal to the faces with the larger area of the concentrator 5 (i.e. to the wall 27 of the spacer 17). What takes place after this expansion is also shown by a comparison of FIGS. 3 and 4: in the case when the temperature increases, the spacer can accommodate the thermal expansion of the LSC 5, thanks to the compression of the compensator element 30. Consequently, damage and mechanical tensions in the structure of the insulating glazing, which could damage the insulating glazing irreparably (in particular on the frame thereof), are avoided.

Any expansions of the LSC in other directions, such as that of the axis Z, are received within the channel 21, which advantageously has dimensions such as to receive said insulating glazing with play.

With a rigid spacer 17 as shown in the figures, which rigid spacer has the channel 21 to contain both the luminescent solar concentrator 5 and the compensator element 30, it is necessary to implement solutions in order to permit the electrical coupling between the photovoltaic cells 10 of the solar concentrator 5 and an electrical circuit (not shown) on the exterior of the insulating glazing, which electrical circuit is for example associated with a counter-frame 80 as shown in FIG. 10.

FIGS. 5 and 6 show two possible solutions to this requirement: according to the configuration in FIG. 5, through-holes 37 are provided within the wall 27 of the body of the spacer 17, in order to permit the passage of electrical wires or cables (not shown) connected directly to the photovoltaic cells 10 placed at the end 22 of the LSC 5.

Alternatively, according to the configuration in FIG. 6, the spacer 17 has metal contacts 40 disposed between the compensator element and the photovoltaic cells 10 of the LSC 5 (which metal contacts have sliding connectors, not shown). These contacts 40 are thus connected to similar cables or conductors which reach the exterior of the insulating glazing.

In both the solutions, the electrical connection is guaranteed between the solar cells and an external electrical circuit (which in itself is known, and is not shown), which circuit is associated with the fixed structure (for example the counter-frame 80) which surrounds the frame of the insulating glazing (fixed structure shown in FIG. 12, which will be described hereinafter).

In the variant in FIGS. 7-9 (where elements corresponding to those already described in relation to FIGS. 1-6 are indicated with the same numerical references), the use of partially flexible spacers 17 is shown, which spacers are disposed between each panel 4 and 6, and the LSC 5. Each spacer comprises a form substantially in the shape of an overturned “U”, with parallel arms 47 and 48 which are rigid, and are glued by means of adhesive layers or adhesive 240 and 241 respectively on the outer and inner panels 4 and 6 of the insulating glazing (the sides 47) and the body 7 of the luminescent solar concentrator 5 (the sides 48).

In the case in question, the spacers 17 are not completely rigid as in the case previously described and shown in FIGS. 1-6, but have a flexible portion 50 which connects the arms 47 and 48. This portion 50 of each spacer 17 allows the spacer to accommodate the thermal expansions or contractions of the luminescent solar concentrator 5 relative to the other panels 4 and 6 made of a different material, without the insulating glazing 1 undergoing damage caused by mechanical stress.

The comparison of FIGS. 8 and 9 shows the deformation of each spacer 17, when the LSC 5 is deformed (arrow H) when it is subjected to thermal variation. It will be appreciated that, with the solution in FIGS. 7-9, the frame of the insulating glazing must have free spaces at the edges 7A-7D for deformation of the LSC 5.

It should be noted that the portion 50 of the spacer 17 comprises an intermediate yielding or resilient or plastics component 55 which facilitates the deformation of the portion 50, whilst maintaining the rigidity of the insulating glazing.

Usually, the photovoltaic cells 10 are coupled according to a specific plan, as shown in FIG. 10B. After this coupling, the distribution of photons emitted along the perimeter of an LSC is not constant, as shown by FIG. 10A.

More particularly, by way of non-limiting example, FIG. 10A shows the emission profile of a side of an LSC with a length of 15 cm (where the number of photons emitted is indicated in standardised units relative to the maximum value emitted from the centre of the side of the concentrator). It should be noted that the non-homogenous distribution of emission of light is an intrinsic characteristic of the LSC, and is therefore independent from the dimensions thereof. In particular, the number of photons emitted from the centre of a side is always greater than the number of the photons emitted from the two ends of the side itself. Consequently, the photovoltaic cells coupled thereto are exposed to an intensity of light radiation which is spatially not uniform.

This leads to the fact that the current produced by a string of solar cells with equal dimensions connected to one another in series, and coupled to the side of the concentrator, is limited to the current produced by the least lit cell of the string.

This effect is shown in the histogram in FIG. 10A, where the spatial distribution of the electrical current produced by solar cells 10 with an identical area (histogram) follows the non-homogenous distribution of photons emitted from the side of the concentrator (continuous line). Consequently, the cells 10 which are placed at the ends of the side produce current which is significantly less than the cells which are placed at the centre of the side itself. This introduces an intrinsic limit to the electrical current which can be extracted from the entire string of cells, which limit is specifically dictated by the current generated by the least lit cells.

A solution to this problem which makes it possible to maximise the electrical power which can be obtained from a solar concentrator is to use photovoltaic cells with different dimensions, such as to compensate for the different intensity of light emission along the side of the concentrator. This can be carried out according to the plan in FIG. 11B, in which cells 10M with a larger area are placed at sections with lower lighting of the side of the concentrator. In this case, since the current is proportional to the product of density of lighting and area lit, as indicated in FIG. 11A, the profile of electrical current generated does not follow the irregular development of the photons emitted along the side of the concentrator, but on the other hand is constant. This results in a total value of electrical current which can be extracted from the side of the concentrator which is significantly greater than the case previously described for solar cells with constant dimensions.

According to a further characteristic of the invention, the insulating glazing 1 operates as a self-powered “smart window”. In this case, as shown in FIG. 12, the electrical energy produced by the light which strikes the luminescent solar concentrator or LSC 5 is directed to a battery 81 which is secured on the frame of the insulating glazing or on the counter-frame 80 of a window, by means of an electrical connection 811.

The battery 81 is connected to the photovoltaic cells 10 of the insulating glazing 1. Various users or devices which can have various functions can be connected to the battery 81. For example, the battery 81 can be connected by means of an electrical cable 83 to an electro-chromic device 82 which can obscure the insulating glazing, and/or a device (electric motor) for movement of a curtain (not shown), and/or a Wi-Fi repeater, LED lights, or another type of lighting device, and/or alarm devices (which for example are connected to the opening of the window, or are volumetric), and/or a Hi-Fi repeater or other electrical devices, for example sensors of various types; all of these are placed on the interior or the exterior of the insulating glazing.

An electrical socket and/or a USB socket 84 can also be connected via a cable 87 to the battery 81.

It is also possible to use the cells 10 in order to supply power directly to said electronic devices, without needing to provide a battery.

A description has been provided of various embodiments of the present invention. It will be appreciated that other variants are possible, such as the one which includes the panels 4 and 6 and a plurality of intermediate LSCs 5. These solutions also come within the scope of the invention as defined by the appended claims.

1. An insulating glazing comprising at least two panels, wherein at least one of these panels is a luminescent solar concentrator, the luminescent solar concentrator being deformable in a direction (H) which is orthogonal to an axis (Z) perpendicular to its faces with a larger area, further to a variation of the temperature thereof and thermal expansion thereof, the insulating glazing comprising two panels which are made of transparent material, disposed at outer faces of the insulating glazing, and a luminescent solar concentrator which is placed between said two panels at opposite edges, the luminescent solar concentrator cooperating with a spacer unit which spaces it from each adjacent panel made of transparent material, the spacer unit comprising two portions with a form in the shape of an overturned “U” delimiting a channel in which an end of the luminescent solar concentrator is placed, said portions with a form in the shape of an overturned “U” being interconnected by a wall delimiting said channel, said spacer unit comprising means which can receive the deformation of the solar concentrator.

2. The insulating glazing according to claim 1, wherein said means which can receive the deformation of the solar concentrator comprise, placed within the channel of the spacer unit, a compensator element, which is placed between said wall of the channel and said end of the luminescent solar concentrator, said element being yielding, and being able to withstand and compensate for the deformation of the luminescent solar concentrator with which this element is in contact.

3. The insulating glazing according to claim 2, wherein the two portions of the spacer unit are detached from the luminescent solar concentrator.

4. The insulating glazing according to claim 2, wherein said compensator element is made of plastics material, rubber, or of foam material.

5. (canceled)

6. (canceled)

7. The insulating glazing according to claim 1, wherein said spacer unit comprises holes for the passage of electrical connections which connect the luminescent solar concentrator to an electrical circuit on the exterior of the insulating glazing.

8. The insulating glazing according to claim 1, wherein said spacer unit comprises electrical contact means which can co-operate by sliding with connectors of the luminescent solar concentrator, said means for electrical contact by sliding being connected to an electrical circuit on the exterior of the insulating glazing.

9. The insulating glazing according to claim 1, further comprising an electrical circuit constituted by solar cells with a variable dimension, which electrical circuit can maximise the electrical current which can be extracted.

10. The insulating glazing according to claim 1, wherein it is connected to electrical and/or electronic devices, optionally by means of a battery which can accumulate the energy produced by the luminescent solar concentrator, and to which said electrical and/or electronic devices are connected directly, these devices being an out of actuator means for a curtain, electro-chromatic means, alarm devices, or electrical power supply sockets.

11. The insulating glazing according to claim 10, wherein said electrical/electronic devices are associated with a counter-frame of the insulating glazing.

12. The insulating glazing according to claim 1, wherein it is part of a window or French window.

13. The insulating glazing of claim 1, where the transparent material is glass or a plastic material.
